(19) United States
(12) Patent Application Publication
(10) Pub. No.: US 2011/0139501 A1
(43) Pub. Date: Jun. 16, 2011

(54) ELECTRONIC CHIP AND SUBSTRATE WITH SHAPED CONDUCTOR

(76) Inventors: LIN CHING-SAN, Wufeng Township (TW); Wu Shih-Feng, Xinying City (TW)

(21) Appl. No.: 12/968,745

(22) Filed: Dec. 15, 2010

(30) Foreign Application Priority Data
Dec. 16, 2009 (TW) 098143123

(51) Int. Cl. H05K 1/18

(52) U.S. Cl. 174/260

(57) ABSTRACT

An electronic chip including a plurality of conducting pins is provided. The conducting pins are located on an exterior surface of the electronic chip and provides via a conductive adhesive a plurality of electrical connections between the electronic chip and an external circuit. Among the conducting pins, a first conducting pin is adjacent to a second conducting pin. A first void is formed in a first corner of the first conducting pin near the second conducting pin. A flow space is accordingly provided for conducting particles in the conductive adhesive to flow through.

### CROSS-REFERENCE TO RELATED APPLICATION

This application claims priority based on Taiwanese Patent Application No. 098143123, filed on Dec. 16, 2009, the disclosure of which is incorporated herein by reference in its entirety.

### BACKGROUND OF THE INVENTION

1. Field of the Invention

The present invention generally relates to external conducting pins of an electronic chip or a substrate. More particularly, this invention relates to a skill for decreasing the rate of short circuits between the external conducting pins of an electronic chip or a substrate.

2. Description of the Prior Art

With the recent advancement in technology, many commercial, household, and personal electronic devices have become widely used. Besides functional upgrades and stylistic design changes, developments of electronic devices have been trending towards device miniaturization in order to enhance the convenience of mobility and usage. Due to the advancement in manufacturing and packaging techniques, a majority of electronic chips presently produced have circuit areas/volumes miniaturized from previous renditions and consequently satisfy the product requirement for light weight specification. However, for designers and manufacturers, the mentioned changes also produce many new problems and challenges to solve.

The schematic views of conducting an electronic chip and an external circuit via conductive adhesive in prior arts are shown in FIG. 1A to 1D. A plurality of conducting pins 12, located on the exterior surface of an electronic chip 10, is utilized for providing the electrical connections between the electronic chip 10 and an external circuit 16. For example, the plurality of conducting pins 12 can be used as pins for transferring data or voltage criterion.

In practice, a conductive adhesive 14 generally consists of a resin having a plurality of conducting particles 14A. As shown in FIG. 1B, after the electronic chip 10 has been compressed together with the conducting adhesive 14 and the external circuit 16, each conducting pin 12 will via the conducting particles 14A be electrically connected to their corresponding conducting points 18, forming electrically conductive paths.

During the process of compressing together the electronic chip 10, the conducting adhesive 14 and the external circuit 16, the portions of conducting adhesive 14 (and the conducting particles 14A within thereof) not sandwiched between the conducting pins 12 and the conducting points 18 will be pushed out to the open spaces surrounding the conducting pins 12 and the conducting points 18. Theoretically, since the conducting particles 14A in the open spaces surrounding the conducting pins 12 have not been directly compressed with sufficient pressure, said conducting particles 14A should not be in contact with each other and thereby as a result form a conductive insulation for the open spaces.

However, as previously mentioned, the area/volume of electronic chips are gradually decreasing. In the scenario where the number of the conducting pins on the exterior of electronic chips remains unchanged, miniaturization of electronic chips leads to a decrease in the volume of an electronic chip, and further results in a greater increase in the density of the pins in the given area as the proximity between each individual pin decreases. Consequently, the probability of short circuits to arise between adjacent conducting pins will increase since the distance between adjacent conducting pins have been decreased. As shown in FIG. 1B, while the distance between adjacent conducting pins 12 possibly could have been 220 μm in the past, the distance may now be approximately reduced to 15 μm. With respect to the conducting particle 14A having a diameter of 3 μm, the length between adjacent conducting pins 12 is merely only a factor of 5 to 6 times of the diameter.

As shown in the area defined by the dotted line 19 in FIG. 1C, in the scenario of a high concentration of conducting particles 14A, the conducting particles between adjacent conducting pins 12 may contact each other and cause a short circuit to form between the adjacent conducting pins 12. Damage to the electronic chip 10 or the external circuit 16 due to the resulting short circuit is highly probable, possibly also causing burn damage to them.

A partial top plan view of an external surface of the electronic chip 10 having conducting pins 12 (not included are the external circuit 16 and the conducting points 18) is shown in FIG. 1D. The shape of the cross-section of the pin 12, parallel to the external surface of the electronic chip 10, is typically a rectangle. The inventor of the present invention finds that the mobile conducting particles 14A in the open spaces are easily affected by the right angle corners of the electronic pins 12, resulting in the restriction of mobility of the conducting particles 14A. The restriction increases the possibility of conducting particles 14A coming in contact with each other. As such, contacting conducting particles 14A cause a short circuit to occur between the conducting pins 12A and 12B by forming a link between the two conducting pins.

### SUMMARY OF THE INVENTION

It is an object of the present invention to provide a solution to the above mentioned problems. The present invention changes the shapes of the conducting pins and may change the shape of the conducting points as well. By providing more mobility space for the conducting particles of the conducting adhesive, the probability of short circuits to occur between the conducting pins and/or the conducting points can be decreased.

An embodiment of the present invention is an electronic chip having a plurality of conducting pins. The plurality of conducting pins is located on the exterior surface of the electronic chip to provide via the conductive adhesive a plurality of electrical connections between the electronic chip and an external circuit. Among the conducting pins, a first conducting pin is adjacent to a second conducting pin. A first void is formed in a first corner of the first conducting pin near the second conducting pin, wherein a flow space in the conductive adhesive for conducting particles to flow through is accordingly provided.

Another embodiment of the present invention is a substrate having a plurality of conducting points. The plurality of conducting points, located on the exterior surface of the substrate, provides via the conductive adhesive a plurality of electrical connections between the substrate and an electronic chip. Among the conducting pins, a first conducting pin is adjacent to a second conducting pin. A first void is formed in a first corner of the first conducting pin near the second conducting pin, wherein a flow space in the conductive adhesive for conducting particles to flow through is accordingly provided.

The concept disclosed in the present invention is applicable for use in various kinds of electronic chips and substrates. The spirit and advantages of the present invention can further be understood through the following descriptions in conjunction with the provided diagrams.

### BRIEF DESCRIPTION OF THE DRAWINGS

FIG. 1A to 1D are schematic views of conducting an electronic chip and an external circuit via conductive adhesive in prior arts;

FIG. 2A to 2C are schematic views of conducting pins in an embodiment of the present invention; and

FIG. 3A to 3F and FIG. 4A, 4B are schematic views of conducting pins having different shapes.

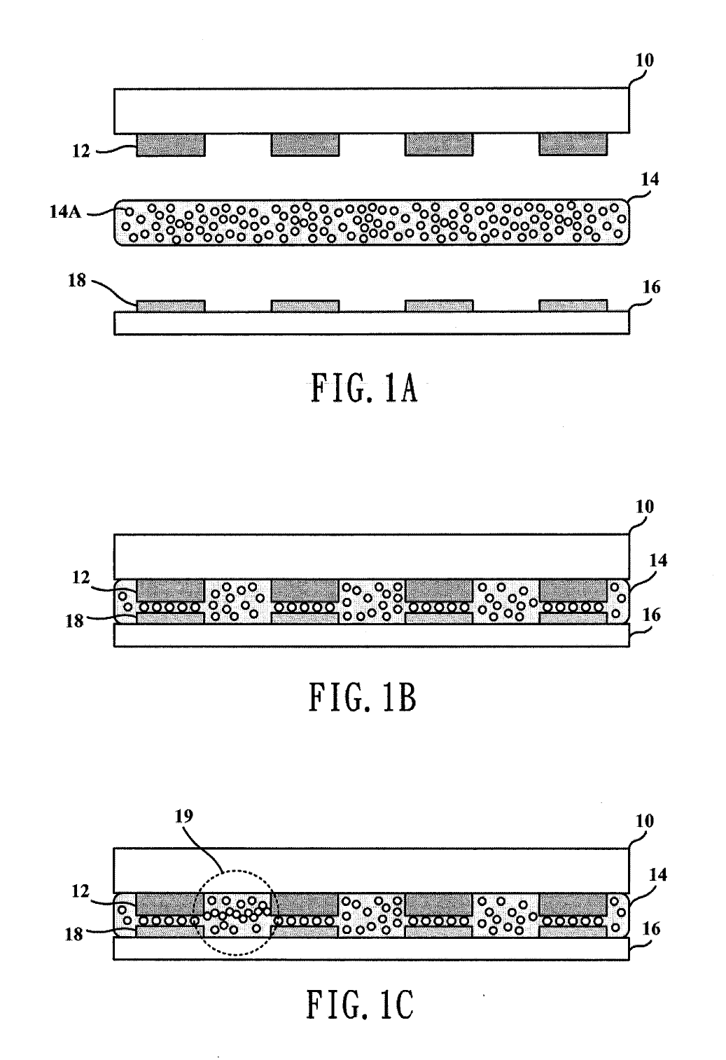

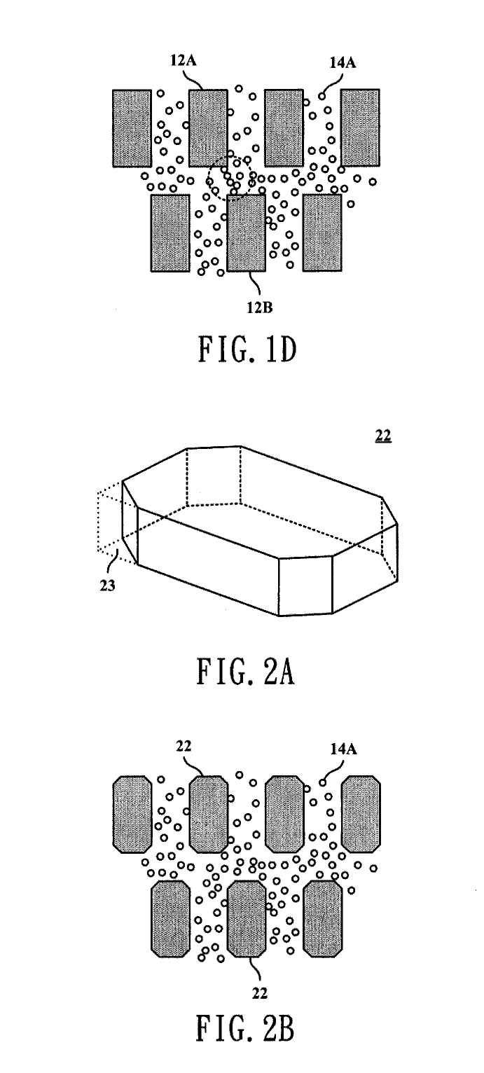

### DETAILED DESCRIPTION OF THE PREFERRED EMBODIMENT

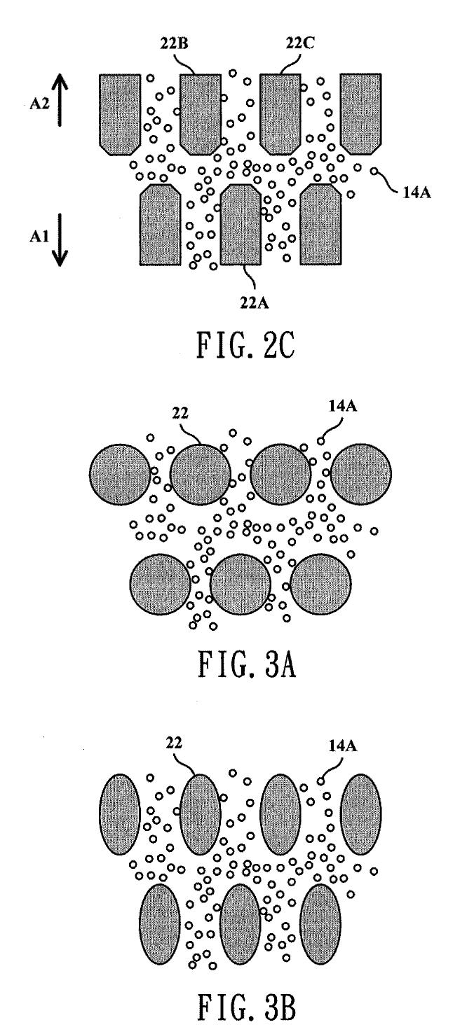

The first embodiment of the present invention is an electronic chip having a plurality of conducting pins. The plurality of conducting pins is located on an exterior surface of the electronic chip, providing via the conductive adhesive a plurality of electrical connections between the electronic chip and an external circuit. As shown in a schematic view in FIG. 2A of a conducting pin 22 in an embodiment of the present invention, the conducting pin 22 can be seen as a polygonal pillar formed by cutting off four corners of a rectangular pillar. As shown in FIG. 2A, the cross-section, parallel to the plane of the external surface of the electronic chip, of the pillar is substantially an octagonal rectangle.

In practice, the conductive adhesive for conducting the electronic chip and the external circuit may be an anisotropic conductive adhesive (ACA), an anisotropic conductive film (ACF), or any other kinds of gel with conducting particles.

A partial top plan view of the exterior surface of the electronic chip having a plurality of conducting pins 22 is shown in FIG. 2B. As shown in FIG. 2B, the corners of each conducting pin 22 forms a void (i.e. the area indicated by the dotted lines and marked as 23 in FIG. 2A), to provide a flow space in the conductive adhesive for conducting particles 14A to flow through.

In comparison to the conducting pins with right angles of the prior arts, the conducting particles 14A in the present invention are not restricted by any right angles during the process of compressing together the electronic chip and the external circuit, flowing relatively easier through the space between the conducting pins. Consequently, the probability of a short circuit occurring between the conducting pins 22 is decreased.

However, in other embodiments of the present invention, not all four corners of each conducting pin 22 needs to form a void. As shown in FIG. 2C, two corners of a first conducting pin 22A are respectively adjacent to a second conducting pin 22B and a third conducting pin 22C, wherein each corner forms a void. A corner of the second conducting pin 22B adjacent to the first conducting pin 22A and a corner of the third conducting pin 22C adjacent to the first conducting pin 22A respectively form voids. In the present embodiment, the first conducting pin 22A has no adjacent conducting pin in the A1 direction. Therefore, the first conducting pin 22A does not form any void in the lower two corners shown in FIG. 2C. Similarly, the second conducting pin 22B and the third conducting pin 22C have no adjacent conducting pin in the A2 direction. Therefore, the mentioned two conducting pins do not form any void in the upper corners shown in FIG. 2C.

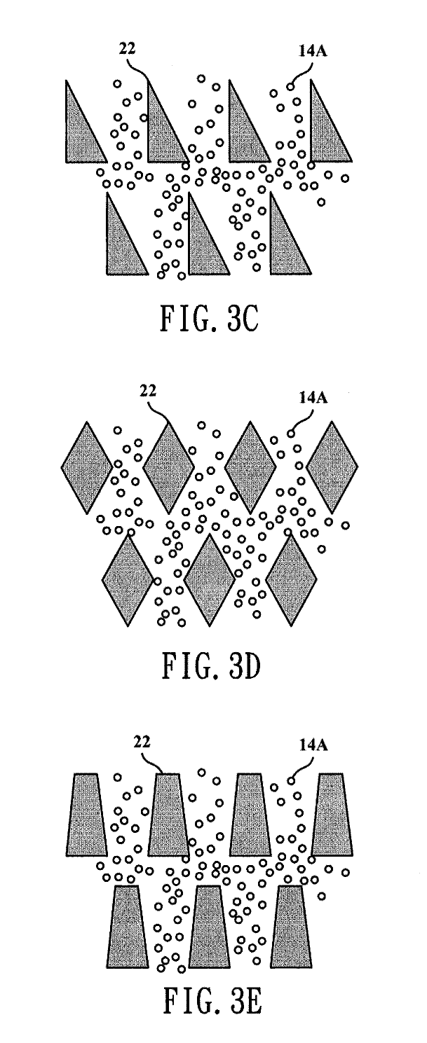

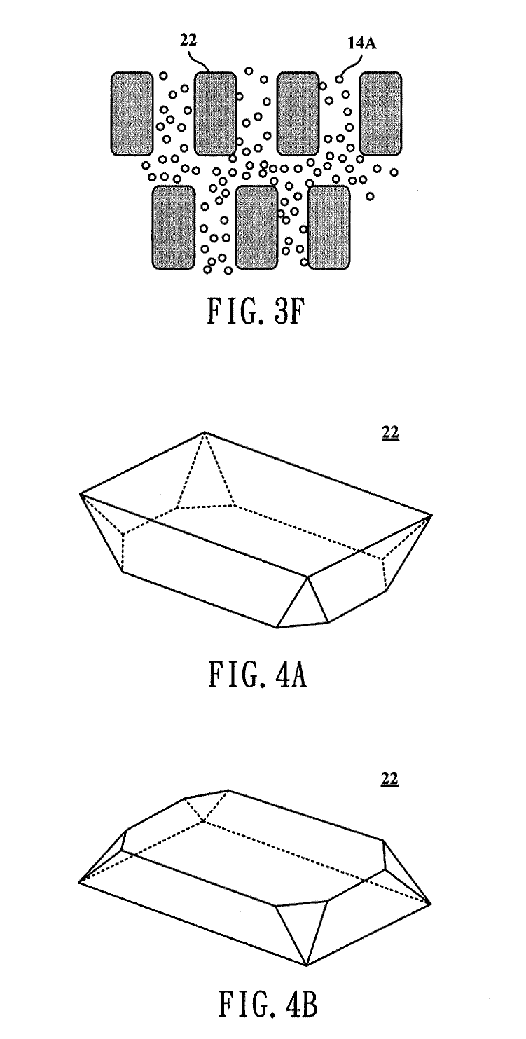

The cross-section of the conducting pin is not limited to an octagonal rectangular shape; a circle, an ellipse, a triangle, a rhombus, a trapezium, or any other polygon formed by changing the corners of a rectangle to a curved side as respectively shown in FIG. 3A to 3F are also feasible.

The conducting pins of the present invention can also be formed as accordingly to the shape shown in FIG. 4A or 4B, wherein the two embodiments illustrate the circumstances in which the upper surface area differs from that of the lower surface area in the conducting pin 22. As shown in FIG. 4A, the lower surface area of the conducting pin 22 conducting with the electronic chip is smaller than the upper surface area. As shown in FIG. 4B, the lower surface area of the conducting pin 22 conducting with the electronic chip is larger than the upper surface area. In the preferred embodiment, the main body and the voids of the conducting pin 22 can be fabricated by an etching process.

In comparison to the conducting pins with right angles of the prior arts, the mentioned multiform conducting pins 22 provide for the conducting particles flow paths that are difficult to obstruct. Consequently, the probability that a short circuit occurs between the conducting pins 22 can be decreased.

The second embodiment of the present invention is a substrate having a plurality of conducting points. The plurality of conducting points is located on the exterior surface of the substrate, providing via the conductive adhesive a plurality of electrical connections between the substrate and an electronic chip. Among the conducting points, a first conducting point is adjacent to a second conducting point. A first void is formed in a corner of the first conducting point near the second conducting point, wherein a flow space is accordingly provided in the conductive adhesive for conducting particles to flow through.

The conducting points may be formed according to the shapes shown in FIG. 2A, 2B, 3A to 3F, 4A, or 4B, and can be matched with the conducting pins mentioned in the above embodiment. For example, a conducting point having an octangular cross-section can be matched but not restricted to a conducting pin 22 having the same cross-sectional shape. In comparison to the conducting points with right angles of the prior arts, the mentioned multiform conducting points provide for the conducting particles flow paths that are difficult to obstruct.

The present invention as described above provides a scheme to change the shapes of the conducting pins and/or the conducting points. In providing greater flow spaces for the conducting particles of the conducting adhesive, the probability of short circuits occurring between the conducting pins and/or the conducting points can be decreased. The concept of the present invention is applicable for use in various kinds of electronic chips and substrates and is especially suited for electronic chips and substrates having taller conducting pins and/or conducting points.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. An electronic chip, comprising:
a plurality of conducting pins disposed on an exterior surface of the electronic chip to provide via a conductive adhesive a plurality of electrical connections between the electronic chip and an external circuit, wherein among the conducting pins a first conducting pin is adjacent to a second conducting pin, a first void is formed in a first corner of the first conducting pin near the second conducting pin, and a flow space is accordingly provided for conducting particles in the conductive adhesive to flow through.

2. The electronic chip of claim 1, wherein the first conducting pin is a pillar, the cross-section of the pillar parallel to the plane of the external surface is a circle, a triangle, a rhombus, trapezium, or an octagon.

3. The electronic chip of claim 1, wherein the first conducting pin is a pillar, the cross-section of the pillar parallel to the plane of the external surface is basically a rectangle or a variation of a rectangle, the first corner has a curved side.

4. The electronic chip of claim 1, wherein the first conducting pin has a lower surface conducting the external surface of the electronic chip, the lower surface has a first area, the first conducting pin has an upper surface having a second area, the first area is larger than the second area.

5. The electronic chip of claim 1, wherein the first conducting pin has a lower surface conducting the external surface of the electronic chip, the lower surface has a first area, the first conducting pin has an upper surface having a second area, the first area is smaller than the second area.

6. The electronic chip of claim 1, wherein a second void is formed in a second corner of the second conducting pin near the first conducting pin.

7. A substrate, comprising:
a plurality of conducting points disposed on an exterior surface of the substrate to provide via a conductive adhesive a plurality of electrical connections between the substrate and an electronic chip, wherein among the conducting points a first conducting point is adjacent to a second conducting point, a first void is formed in a first corner of the first conducting point near the second conducting point, and a flow space is accordingly provided for conducting particles in the conductive adhesive to flow through.

8. The substrate of claim 7, wherein the first conducting point is a pillar, the cross-section of the pillar parallel to the plane of the external surface is a circle, a triangle, a rhombus, trapezium, or an octagon.

9. The substrate of claim 7, wherein the first conducting point is a pillar, the cross-section of the pillar parallel to the plane of the external surface is basically a rectangle or a variation of a rectangle, the first corner is a curved side.

10. The substrate of claim 7, wherein the first conducting point has a lower surface conducting the external surface of the substrate, the lower surface has a first area, the first conducting point has an upper surface having a second area, the first area is larger than the second area.

11. The substrate of claim 7, wherein the first conducting point has a lower surface conducting the external surface of the substrate, the lower surface has a first area, the first conducting point has an upper surface having a second area, the first area is smaller than the second area.

12. The substrate of claim 7, wherein a second void is formed in a second corner of the second conducting point near the first conducting point.
